(19) United States
(12) Patent Application Publication
(10) Pub. No.: US 2013/0099297 A1
(43) Pub. Date: Apr. 25, 2013

(54) ELECTROSTATIC DISCHARGE PROTECTION DEVICE

(71) Applicants: Chieh-Wei He, Hsinchu (TW); Qi-An Xu, Hsinchu (TW)

(72) Inventors: Chieh-Wei He, Hsinchu (TW); Qi-An Xu, Hsinchu (TW)

(73) Assignee: MACRONIX INTERNATIONAL CO., LTD., Hsinchu (TW)

(21) Appl. No.: 13/277,796

(22) Filed: Oct. 20, 2011

(51) Int. Cl. H01L 27/092

(52) U.S. Cl. 257/296; 257/355; 257/E27.062

(57) ABSTRACT

An electrostatic discharge protection device electrically connected between a pad and an internal circuit is provided and includes a capacitor, a first resistor, a voltage-drop element and an NMOS transistor. A first end of the capacitor is electrically connected to the pad. A first end of the first resistor is electrically connected to a second end of the capacitor, and a second end of the first resistor is electrically connected to ground. The NMOS transistor and the voltage-drop element are connected in series between the pad and the ground, a gate of the NMOS transistor is electrically connected to the second end of the capacitor, and a bulk of the NMOS transistor is electrically connected to the ground.

### BACKGROUND OF THE INVENTION

1. Field of the Invention

The invention relates to an electrostatic discharge (ESD) protection device. Particularly, the invention relates to a gate-coupled ESD protection device.

2. Description of Related Art

As a complementary metal oxide semiconductor (CMOS) process enters a deep sub-micron scale, many advanced process techniques are used in order to reduce a device size and maintain device characteristics, for example, a relatively thin gate oxide layer, a relatively short channel length, a relatively shallow junction depth, a lightly-doped drain (LDD) structure, and a self-aligned silicide structure, etc. However, the above advanced process techniques may also result in reduction of an electrostatic discharge (ESD) protection capability of an integrated circuit (IC). Therefore, to enhance the device ESD protection capability is an important issue to be developed in design of deep sub-micro devices.

Generally, the existing ICs are all configured with ESD protection devices at input and output pins thereof to prevent damage of the ICs due to ESD phenomenon. The ESD protection device has a plurality of designs, and a commonly used one is a gate-coupled ESD protection device. Under such structure, the ESD protection device includes an N-channel metal oxide semiconductor (NMOS) transistor connected between a pad and the ground, and a gate of the NMOS transistor has a gate-coupled design. In this way, when an ESD event is occurred, an electrostatic signal come from the pad may turn on the NMOS transistor to produce a discharge path, so as to conduct the electrostatic signal to the ground.

On the other hand, when an internal circuit normally operates, the ESD protection device has to turn off the NMOS transistor to avoid generating a leakage current. However, in an actual application, when a rising time of the electrostatic signal come from the pad is shortened, the NMOS transistor often cannot be completely turned off, which may increase the leakage current of the device. In other words, the existing gate-coupled ESD protection device cannot be applied in ICs with a high operating speed.

### SUMMARY OF THE INVENTION

The invention is directed to an electrostatic discharge (ESD) protection device, in which an N-channel metal oxide semiconductor (NMOS) transistor is not easy to be triggered due to a series structure of the NMOS transistor and a voltage-drop element, so that the ESD protection device can be applied in an integrated circuit (IC) with a high operating speed.

The invention is directed to an ESD protection, used to avoid triggering the NMOS transistor during an internal circuit normally operates. In this way, leakage current in the ESD protection device can be reduced.

The invention provides an electrostatic discharge protection device electrically connected between a pad and an internal circuit, where the internal circuit receives an input signal through the pad, and the electrostatic discharge protection device includes a capacitor, a first resistor, a voltage-drop element and an N-channel metal oxide semiconductor (NMOS) transistor. A first end of the capacitor is electrically connected to the pad. A first end of the first resistor is electrically connected to a second end of the capacitor, and a second end of the first resistor is electrically connected to ground. The NMOS transistor and the voltage-drop element are connected in series between the pad and the ground, a gate of the NMOS transistor is electrically connected to the second end of the capacitor, and a bulk of the NMOS transistor is electrically connected to the ground.

In an embodiment of the invention, a drain of the NMOS transistor is electrically connected to the pad, and a source of the NMOS transistor is electrically connected to the ground through the voltage-drop element.

In an embodiment of the invention, the voltage-drop element includes a first diode, an anode of the first diode is electrically connected to the source of the NMOS transistor, and a cathode of the first diode is electrically connected to the ground.

In an embodiment of the invention, the voltage-drop element includes a plurality of second diodes, and the second diodes are connected in series between the source of the NMOS transistor and the ground.

In an embodiment of the invention, a first end of the voltage-drop element is electrically connected to the pad, a second end of the voltage-drop element is electrically connected to a drain of the NMOS transistor and a source of the NMOS transistor is electrically connected to the ground.

In an embodiment of the invention, the voltage-drop element includes a third diode. An anode of the third diode is electrically connected to the pad, a cathode of the third diode is electrically connected to the drain of the NMOS transistor, and the source of the NMOS transistor is electrically connected to the ground.

The invention provides an electrostatic discharge protection device electrically connected between a pad and an internal circuit, where the internal circuit receives an input signal through the pad, and the electrostatic discharge protection device includes a capacitor, a first resistor, a voltage-drop element and an NMOS transistor. The first resistor and the capacitor are electrically connected in series between the pad and a ground. The NMOS transistor has a drain electrically connected to the pad, a gate electrically connected to a connection node between the capacitor and the first resistor, a bulk electrically connected to the ground and a source. The voltage-drop element is electrically connected between the source of the NMOS transistor and the ground.

According to the above descriptions, the NMOS transistor is not easy to be triggered due to a series structure of the NMOS transistor and the voltage-drop element. In this way, although the rising time of the input signal is shortened, the input signal coupled to the gate of the NMOS transistor is not easy to trigger the NMOS transistor. Therefore, the ESD protection device can be applied in an integrated circuit (IC) with a high operating speed, and leakage current in the ESD protection device can also be reduced.

It is to be understood that both the foregoing general description and the following detailed description are exemplary, and are not intended to limit the scope of the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a circuit diagram of an electrostatic discharge (ESD) protection device according to an embodiment of the invention.

FIG. 1B and FIG. 1C are respectively a circuit diagram of an ESD protection device according to another embodiment of the invention.

FIG. 2A is a circuit diagram of an ESD protection device according to still another embodiment of the invention.

FIG. 2B and FIG. 2C are respectively a circuit diagram of an ESD protection device according to another embodiment of the invention.

### DETAILED DESCRIPTION OF DISCLOSED EMBODIMENTS

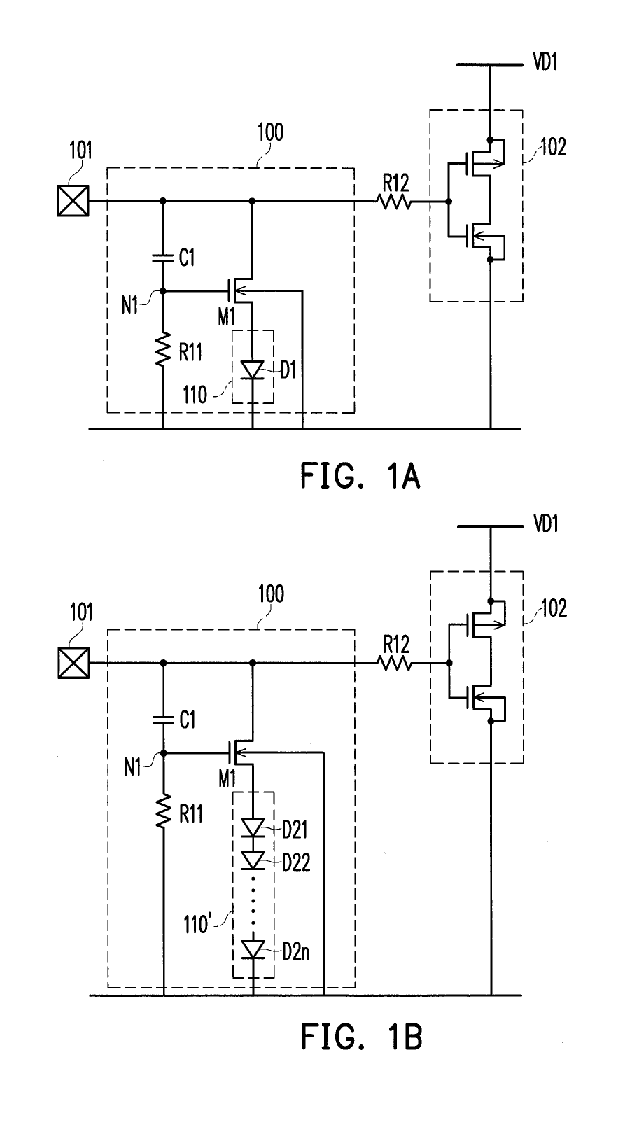

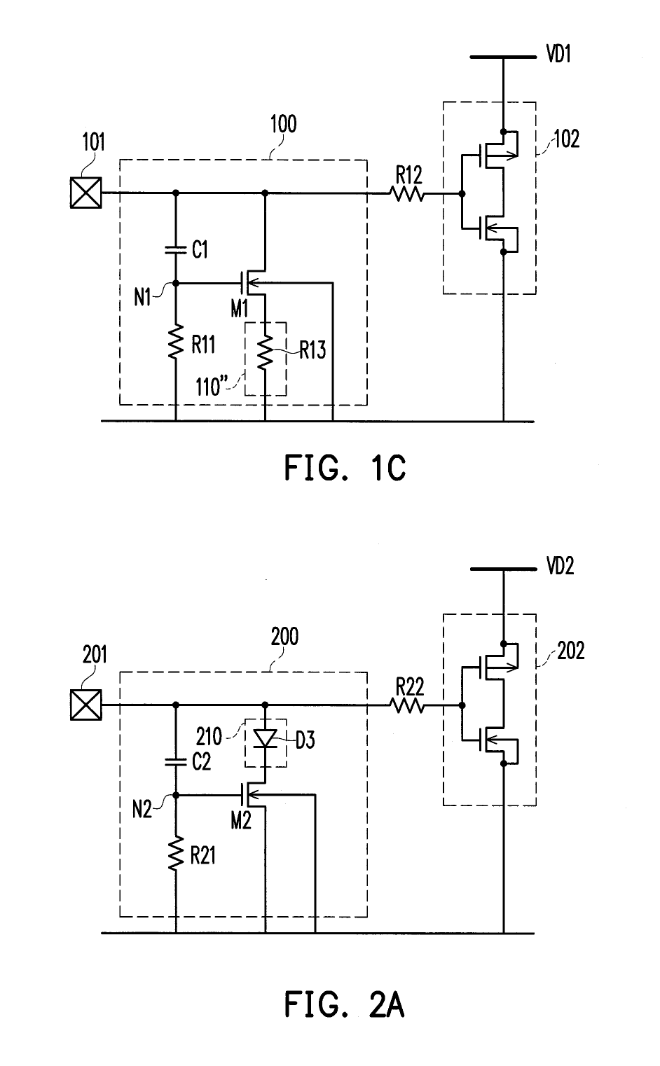

FIG. 1A is a circuit diagram of an electrostatic discharge (ESD) protection device according to an embodiment of the invention. Referring to FIG. 1A, the ESD protection device 100 is electrically connected to a pad 101 and is electrically connected to an internal circuit 102 through a resistor R12. The ESD protection device 100 is used to prevent an electrostatic signal of the pad 101 from damaging the internal circuit 102. When the internal circuit 102 normally operates, the internal circuit 102 is operated under a power voltage VD1, and receives an input signal through the pad 101.

The ESD protection device 100 includes a capacitor C1, a resistor R11, an N-channel metal oxide semiconductor (NMOS) transistor M1 and a voltage-drop element 110. The ESD protection device 100 is a gate-coupled ESD protection device, so that in view of an electrical connection, a first end of the capacitor C1 is electrically connected to the pad 101. Moreover, a first end of the resistor R11 is electrically connected to a second end of the capacitor C1, and a second end of the resistor R11 is electrically connected to a ground. In other words, the resistor R11 is electrically connected in series with the capacitor C1 to form a connection node N1. Moreover, the NMOS transistor M1 and the voltage-drop element 110 are connected in series between the pad 101 and the ground. In addition, a gate of the NMOS transistor M1 is electrically connected to the second end of the capacitor C1, this is, the gate of the NMOS transistor M1 is electrically connected to the connection node N1. A bulk of the NMOS transistor M1 is electrically connected to the ground.

Further, in the present embodiment, the voltage-drop element 110 is disposed below the NMOS transistor M1. Therefore, a drain of the NMOS transistor M1 is electrically connected to the pad 101, and a source of the NMOS transistor M1 is electrically connected to the ground through the voltage-drop element 110. Moreover, in the present embodiment, the voltage-drop element 110 includes a diode D1, where an anode of the diode D1 is electrically connected to the source of the NMOS transistor M1, and a cathode of the diode D1 is electrically connected to the ground.

In operation, the capacitor C1 and the resistor R11 form a delay time, where a rising time of the input signal is greater than the delay time, and the delay time is greater than a rising time of an electrostatic signal come from the pad 101. Therefore, the capacitor C1 and the resistor R11 are equivalent to a detecting circuit for detecting the electrostatic signal, and triggering the NMOS transistor M1 when the electrostatic signal is generated. For example, when an ESD event is occurred, the capacitor C1 is equivalent to short-circuit, and the electrostatic signal triggers the NMOS transistor M1 so that the NMOS transistor M1 is turned on. Now, the NMOS transistor M1 provides a discharge path to conduct the electrostatic signal to the ground. In this way, the electrostatic signal from the pad 101 is prevented from damaging the internal circuit 102.

On the other hand, when the internal circuit 102 normally operates, the capacitor C1 is equivalent to open-circuit, so that the NMOS transistor M1 cannot be turned on. Moreover, based on the series structure of the NMOS transistor M1 and the voltage-drop element 110, a turn-on condition of the NMOS transistor M1 becomes more stringent, so that a turn off state of the NMOS transistor M1 can be more complete.

For example, since the voltage-drop element 110 is connected to the source of the NMOS transistor M1, a cross voltage of the voltage-drop element 110 may increase a source voltage of the NMOS transistor M1. Therefore, in order to turn on the NMOS transistor M1, a gate voltage of the NMOS transistor M1 has to be relatively increased. Moreover, a drain-source voltage (Vds) of the NMOS transistor M1 is decreased as the source voltage is increased, which avails reducing a leakage current. On the other hand, the cross voltage of the voltage-drop element 110 may result in a fact that a bulk-source voltage (Vbs) of the NMOS transistor M1 is smaller than 0, so as to increase a threshold voltage of the NMOS transistor M1. In this way, in order to turn on the NMOS transistor M1, a gate-source voltage (Vgs) of the NMOS transistor M1 has to be relatively increased.

In other words, when the internal circuit 102 normally operates, the NMOS transistor M1 is not easy to be triggered due to the series structure of the NMOS transistor M1 and the voltage-drop element 110. Therefore, although a rising time of the input signal is shortened, the input signal coupled to the gate of the NMOS transistor M1 is not easy to trigger the NMOS transistor M1. Therefore, the ESD protection device 100 can be applied in an integrated circuit (IC) with a high operating speed, and leakage current in the ESD protection device 100 can also be reduced.

It should be noticed that although an implementation of the voltage-drop element 110 is provided in the embodiment of FIG. 1A, the invention is not limited thereto. For example, FIG. 1B and FIG. 1C are respectively a circuit diagram of an ESD protection device according to another embodiment of the invention. A main difference between FIG. 1B and FIG. 1A is that a voltage-drop element 110′ of FIG. 1B is composed of a plurality of diodes D21-D2n, and the diodes D21-D2n are connected in series between the source of the NMOS transistor M1 and the ground. Moreover, a main difference between FIG. 1C and FIG. 1A is that a voltage-drop element 110″ of FIG. 1C is composed of a resistor R13, and a first end of the resistor R13 is electrically connected to the source of the NMOS transistor M1, and a second end of the resistor R13 is electrically connected to the ground. Moreover, a resistance of the resistor R11 is more than 100 times greater than a resistance of the resistor R13. Connection relations and operation principles of various components of FIG. 1B and FIG. 1C are similar to that of FIG. 1A, and details thereof are not repeated.

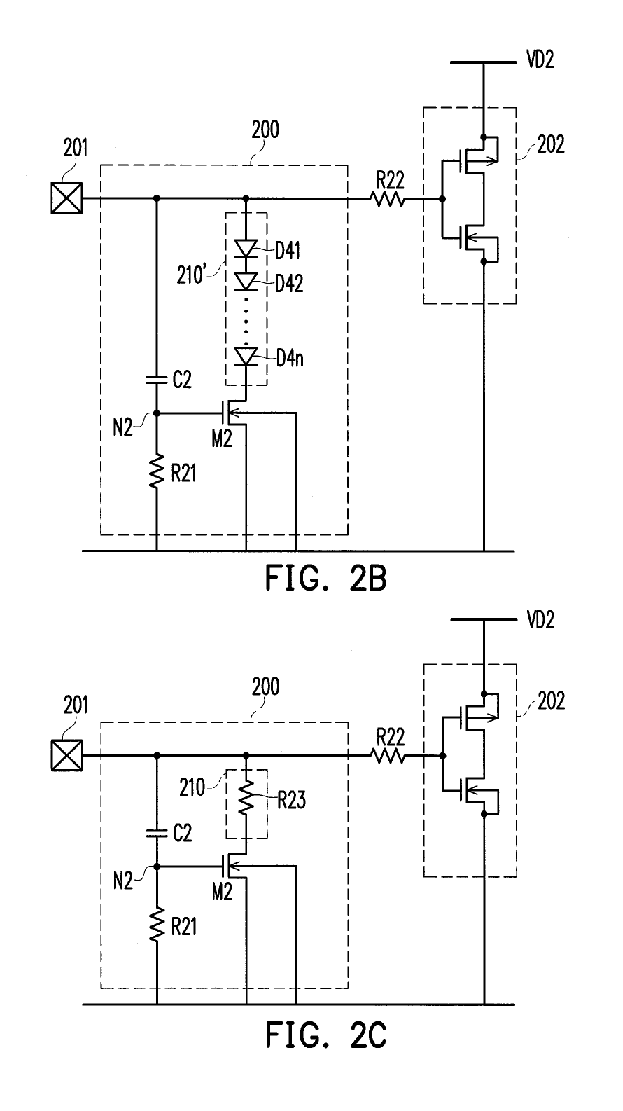

FIG. 2A is a circuit diagram of an ESD protection device according to still another embodiment of the invention. Referring to FIG. 2A, the ESD protection device 200 is electrically connected to a pad 201 and is electrically connected to an internal circuit 202 through a resistor R22. The ESD protection device 200 is used to prevent an electrostatic signal of the pad 201 from damaging the internal circuit 202. When the internal circuit 202 normally operates, the internal circuit 202 is operated under a power voltage VD2, and receives an input signal through the pad 201.

The ESD protection device 200 includes a capacitor C2, a resistor R21, an NMOS transistor M2 and a voltage-drop element 210. A connection structure of the capacitor C2, the resistor R21 and the resistor R22 is the same to the connection structure of the capacitor C1, the resistor R11 and the resistor R12 of the embodiment of FIG. 1A, so that details thereof are not repeated. Moreover, similar to the embodiment of FIG. 1A, the NMOS transistor M2 and the voltage-drop element 210 are connected in series between the pad 201 and the ground. In addition, a gate of the NMOS transistor M2 is electrically connected to a second end of the capacitor C2, this is, the gate of the NMOS transistor M2 is electrically connected to a connection node N2 between the capacitor C2 and the resistor R21. A bulk of the NMOS transistor M2 is electrically connected to the ground.

Further, a main difference between FIG. 2A and FIG. 1A is that the voltage-drop element 210 of FIG. 2A is disposed above the NMOS transistor M2. Therefore, a first end of the voltage-drop element 210 is electrically connected to the pad 201, a second end of the voltage-drop element 210 is electrically connected to a drain of the NOS transistor M2 and a source of the NMOS transistor M2 is electrically connected to the ground. Moreover, in the embodiment of FIG. 2A, the voltage-drop element 210 includes a diode D3, where an anode of the diode D3 is electrically connected to the pad 201, and a cathode of the diode D3 is electrically connected to the drain of the NMOS transistor M2.

In operation, the capacitor C2 and the resistor R21 form a delay time, where a rising time of the input signal is greater than the delay time, and the delay time is greater than a rising time of an electrostatic signal come from the pad 201. Therefore, when an ESD event is occurred, the capacitor C2 is short circuited, and the electrostatic signal triggers to turn on the NMOS transistor M2. Now, the NMOS transistor M2 provides a discharge path to conduct the electrostatic signal to the ground.

On the other hand, when the internal circuit 202 normally operates, the capacitor C2 is equivalent to open-circuit, so that the NMOS transistor M2 cannot be turned on. Moreover, based on the series structure of the NMOS transistor M2 and the voltage-drop element 210, a turn-on condition of the NMOS transistor M2 becomes more stringent, so that a turn off state of the NMOS transistor M2 can be more complete.

For example, since the voltage-drop element 210 is connected to the drain of the NMOS transistor M2, a cross voltage of the voltage-drop element 210 may decrease a drain voltage of the NMOS transistor M2. Therefore, a drain-source voltage (Vds) of the NMOS transistor M2 is decreased as the drain voltage is decreased, which avails reducing a leakage current. In other words, when the internal circuit 202 normally operates, the NMOS transistor M2 is not easy to be triggered due to the series structure of the NMOS transistor M2 and the load device 210.

In addition, the voltage-drop element 210 of FIG. 2A can also be implemented through other structures. For example, FIG. 2B and FIG. 2C are respectively a circuit diagram of an ESD protection device according to another embodiment of the invention. A main difference between FIG. 2B and FIG. 2A is that a voltage-drop element 210′ of FIG. 2B is composed of a plurality of diodes D41-D4n, and the diodes D41-D4n are connected in series between the pad 201 and the drain of the NMOS transistor M2.

Moreover, a main difference between FIG. 2C and FIG. 2A is that a voltage-drop element 210″ of FIG. 2C is composed of a resistor R23, and a first end of the resistor R23 is electrically connected to the pad 201, and a second end of the resistor R23 is electrically connected to the drain of the NMOS transistor M2. Moreover, a resistance of the resistor R21 is more than 100 times greater than a resistance of the resistor R23. Connection relations and operation principles of various components of FIG. 2B and FIG. 2C are similar to that of FIG. 2A, and details thereof are not repeated.

In summary, the NMOS transistor is not easy to be triggered due to the series structure of the NMOS transistor and the voltage-drop element. In this way, although the rising time of the input signal is shortened, the input signal coupled to the gate of the NMOS transistor is not easy to trigger the NMOS transistor. Therefore, the ESD protection device can be applied in an integrated circuit (IC) with a high operating speed, and leakage current in the ESD protection device can also be reduced.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An electrostatic discharge protection device, electrically connected between a pad and an internal circuit, wherein the internal circuit receives an input signal through the pad, the electrostatic discharge protection device comprising:
a capacitor;
a first resistor, wherein the first resistor and the capacitor are electrically connected in series between the pad and a ground;
an N-channel metal oxide semiconductor (NMOS) transistor, having a drain electrically connected to the pad, a gate electrically connected to a connection node between the capacitor and the first resistor, a bulk electrically connected to the ground and a source; and
a voltage-drop element, electrically connected between the source of the NMOS transistor and the ground.

2. The electrostatic discharge protection device as claimed in claim 1, wherein the voltage-drop element comprises a first diode, an anode of the first diode is electrically connected to the source of the NMOS transistor, and a cathode of the first diode is electrically connected to the ground.

3. The electrostatic discharge protection device as claimed in claim 1, wherein the voltage-drop element comprises a plurality of second diodes, and the second diodes are connected in series between the source of the NMOS transistor and the ground.

4. The electrostatic discharge protection device as claimed in claim 1, wherein the capacitor and the first resistor form a delay time, a rising time of the input signal is greater than the delay time, and the delay time is greater than a rising time of an electrostatic signal come from the pad.

5. An electrostatic discharge protection device, electrically connected between a pad and an internal circuit, wherein the internal circuit receives an input signal through the pad, the electrostatic discharge protection device comprising:
a capacitor, having a first end electrically connected to the pad;
a first resistor, having a first end electrically connected to a second end of the capacitor, and a second end electrically connected to a ground;
a voltage-drop element; and
an N-channel metal oxide semiconductor (NMOS) transistor, wherein the NMOS transistor and the voltage-drop element are connected in series between the pad and the ground, a gate of the NMOS transistor is electrically connected to the second end of the capacitor, and a bulk of the NMOS transistor is electrically connected to the ground.

6. The electrostatic discharge protection device as claimed in claim 5, wherein a drain of the NMOS transistor is electrically connected to the pad, and a source of the NMOS transistor is electrically connected to the ground through the voltage-drop element.

7. The electrostatic discharge protection device as claimed in claim 6, wherein the voltage-drop element comprises a first diode, an anode of the first diode is electrically connected to the source of the NMOS transistor, and a cathode of the first diode is electrically connected to the ground.

8. The electrostatic discharge protection device as claimed in claim 6, wherein the voltage-drop element comprises a plurality of second diodes, and the second diodes are connected in series between the source of the NMOS transistor and the ground.

9. The electrostatic discharge protection device as claimed in claim 6, wherein the voltage-drop element comprises a second resistor, a first end of the second resistor is electrically connected to the source of the NMOS transistor, and a second end of the second resistor is electrically connected to the ground, wherein a resistance of the first resistor is more than 100 times greater than a resistance of the second resistor.

10. The electrostatic discharge protection device as claimed in claim 5, wherein a first end of the voltage-drop element is electrically connected to the pad, a second end of the voltage-drop element is electrically connected to a drain of the NMOS transistor and a source of the NMOS transistor is electrically connected to the ground.

11. The electrostatic discharge protection device as claimed in claim 10, wherein the voltage-drop element comprises a third diode, an anode of the third diode is electrically connected to the pad, and a cathode of the third diode is electrically connected to the drain of the NMOS transistor.

12. The electrostatic discharge protection device as claimed in claim 10, wherein the voltage-drop element comprises a plurality of fourth diodes, and the fourth diodes are connected in series between the pad and the drain of the NMOS transistor.

13. The electrostatic discharge protection device as claimed in claim 10, wherein the voltage-drop element comprises a third resistor, a first end of the third resistor is electrically connected to the pad, a second end of the third resistor is electrically connected to the drain of the NMOS transistor, and a resistance of the first resistor is more than 100 times greater than a resistance of the third resistor.

14. The electrostatic discharge protection device as claimed in claim 5, wherein the capacitor and the first resistor form a delay time, a rising time of the input signal is greater than the delay time, and the delay time is greater than a rising time of an electrostatic signal come from the pad.
